(19) United States
(12) Patent Application Publication
(10) Pub. No.: US 2026/0170219 A1
(43) Pub. Date: Jun. 18, 2026

(54) UNIT AND CHIP LEVEL ISOLATION CELL PLACEMENT

(71) Applicant: INTERNATIONAL BUSINESS MACHINES CORPORATION, ARMONK, NY (US)

(72) Inventor: GERALD L STREVIG, III, CEDAR PARK, TX (US)

(21) Appl. No.: 18/978,182

(22) Filed: Dec. 12, 2024

(51) Int. Cl. G06F 30/392

(52) U.S. Cl. CPC G06F 30/392

(57) ABSTRACT

An example method includes placing a plurality of cells, including a plurality of latches and an isolation cell, at initial positions based on a first set of one or more design aspects thereby creating an integrated circuit layout, wherein the isolation cell is configured to isolate circuitry in response to a received control signal. The method includes performing a first optimization on the integrated circuit layout with the plurality of cells at the initial positions, including repositioning the plurality of latches and the isolation cell, concurrently, in the integrated circuit layout based on a second set of one or more design aspects.

### BACKGROUND

The present disclosure relates to methods, apparatus, and products for unit and chip level isolation cell placement.

### SUMMARY

According to embodiments of the present disclosure, various methods, apparatus and products for unit and chip level isolation cell placement are described herein. In some aspects, unit and chip level isolation cell placement includes placing a plurality of cells, including a plurality of latches and an isolation cell, at initial positions based on a first set of one or more design aspects thereby creating an integrated circuit layout, wherein the isolation cell is configured to isolate circuitry in response to a received control signal. Unit and chip level isolation cell placement further includes performing a first optimization on the integrated circuit layout with the plurality of cells at the initial positions, including repositioning the plurality of latches and the isolation cell, concurrently, in the integrated circuit layout based on a second set of one or more design aspects.

### BRIEF DESCRIPTION OF THE DRAWINGS

FIG. 1 sets forth an example computing environment according to aspects of the present disclosure.

FIGS. 2A-2C set forth example latch and isolation cell placements in an integrated circuit layout according to aspects of the present disclosure.

FIG. 3 a flowchart of an example method for latch and isolation cell placement in an integrated circuit layout according to aspects of the present disclosure.

FIG. 4 is a flowchart of an example method for isolation cell movement in an integrated circuit layout according to aspects of the present disclosure.

FIG. 5 is a flowchart of an example method for unit and chip level isolation cell placement according to aspects of the present disclosure.

### DETAILED DESCRIPTION

Some examples disclosed herein relate to the fabrication and design of semiconductor chips and integrated circuits and more specifically to latch and isolation cell placement.

Integrated circuits are used for a wide variety of electronic applications, from simple devices such as wristwatches to the most complex computer systems. A microelectronic integrated circuit (IC) chip can generally be thought of as a collection of logic cells with electrical interconnections between the cells, formed on a semiconductor substrate (e.g., silicon). An IC may include a very large number of cells and require complicated connections between the cells. A cell may be a group of one or more circuit elements such as transistors, capacitors, resistors, inductors, and other basic circuit elements grouped to perform a logic function. Cell types include, for example, core cells, scan cells, and input/output (I/O) cells. Each of the cells of an IC may have one or more pins, each of which in turn may be connected to one or more other pins of the IC by wires. The wires connecting the pins of the IC are also formed on the surface of the chip. For more complex designs, there are typically at least four distinct layers of conducting media available for routing, such as a polysilicon layer and three metal layers, (metal-1, metal-2, and metal 3). The polysilicon layer, metal-1, metal-2 and metal-3 are all used for vertical and/or horizontal routing.

An IC chip is fabricated by first conceiving the logical circuit description, and then converting that logical description into a physical description, or geometric layout. This process is usually carried out using a "netlist," which is a record of all of the nets, or interconnections, between the cell pins. A layout typically includes a set of planar geometric shapes in several layers. The layout is then checked to ensure that it meets all of the design requirements, particularly timing requirements. The result is a set of design files known as an intermediate form that describes the layout. The design files are then converted into pattern generator files that are used to produce patterns called masks by an optical or electron beam pattern generator. During fabrication, these masks are used to pattern a silicon wafer using a sequence of photolithographic steps. The process of converting the specifications of an electrical circuit into a layout is called the physical design.

Cell placement in semiconductor fabrication involves a determination of where particular cells should optimally or near-optimally be located on the surface of an integrated circuit device. Due to the large number of components and the details required by the fabrication process for very large scale integrated (VLSI) devices, physical design is not practical without the aid of computers. As a result, most phases of physical design extensively use computer-aided design (CAD) tools, and many phases have already been partially or fully automated. Automation of the physical design process has increased the level of integration, reduced tum around time and enhanced chip performance. Several different programming languages have been created for electronic design automation (EDA) including Verilog, very high speed integrated circuit hardware description language (VHDL) and time division multiplexing logic (TDML). A typical EDA system receives one or more high level behavioral descriptions of an IC device and translates this high level design language description into netlists of various levels of abstraction.

While various techniques provide placement of cells with regard to their data interconnections, design consideration may also given to constructing a clock network for the cells, which may involve a large amount of power. One method involves the use of local clock buffers (LCBs) to distribute the clock signals. A clock control system may have a clock generation circuit (e.g., a phase-lock loop) that generates a master clock signal that is fed to a clock distribution network that renders synchronized global clock signals at the LCBs. Each LCB adjusts the global clock duty cycle and edges to meet the requirements of respective circuit elements, e.g., local logic circuits or latches (the term "latch" as used herein stands for any clocked element which is usually a sink of a clock distribution network). Generally, each LCB controls a plurality of latches that can be selectively turned on and off by the LCB. The physical arrangement of the LCBs and latches within a semiconductor layout can be influenced by considerations of signal timing, signal congestion, power consumption and placement of other circuit elements. Latches are typically pulled to (away from their ideal locations) and grouped around (i.e., shuddled) an LCB during the design process. Since the clock network may be one of the larger power consumers among all of the interconnects, it may be beneficial to control the capacitive load of the LCBs, each of which may be driving a set of many clock sinks. One approach for reducing the capacitive load is latch clustering, i.e., clusters of latches placed near the respective LCB of their clock domain. Latch clustering combined with LCBs can significantly reduce the total clock wire capacitance which in tum reduces overall clock power consumption.

As discussed above, when placing cells in a circuit layout it may be desirable to cluster and shuddle the latches around an LCB to facilitate data flow. A "shuddle", also known as a "structured huddle", is a collection of latches configured around an LCB. Generally, an LCB can only control a maximum number of latches (e.g., about 50), so many LCBs may be used to accommodate a large number of latches. In some examples, latch placement may involve placing the latches based on timing characteristics and once placed, utilizing a clustering mechanism that involves cloning LCBs and a shuddling mechanism for placing LCBs and arranging the latches around each LCB. However, placing and moving latches without also moving isolation cells can result in routing issues, such as scenic or over-congested routing.

Isolation cells, which may also be referred to as fences, are used in integrated circuit layouts to isolate parts of a design where clocks or power may be turned off to prevent propagation of an unknown state. Isolation cells may be used in a layout to provide a partial good design in which a portion of the design that may not be working properly (e.g., did not get fabricated correctly) is shut down or isolated by one or more isolation cells. Isolation cells may also be used to save power by turning off parts of the design. Isolation cells may be placed on every input and output of the portion of the design that is to be isolated. Examples of the present disclosure automate the placement and repositioning of latches and isolation cells in integrated circuit designs to eliminate the need for designers to manually perform these tasks. This automation increases designer productivity, eliminates designer-introduced bugs in these design aspects, creates a more consistent and thus debuggable design, and provides flexibility to adapt to changing design requirements without costly redesign.

Some examples of unit and chip level isolation cell placement disclosed herein involve the following: (1) initial placement of all cells including latches and isolation cells; (2) repositioning of isolation cells and latches together (e.g., concurrent repositioning); (3) additional movement of isolation cells; (4) huddling latches with a local clock buffer (LCB); and (5) further movement of isolation cells. In some examples, the initial isolation cell placement is executed in parallel and in conjunction with multi-cycle interconnect latch placement. In some examples, after initial placement, the latch and isolation cell locations are again optimized for further efficiency. In some examples, the isolation cell placement is re-optimized iteratively as the latch placement is refined throughout the construction flow.

Some examples disclosed herein are directed to an isolation cell placement method that optimizes routing and timing for nets with isolation cells in unit and chip level physical design hierarchy. Some examples improve designer efficiency by reducing manual work, and improve quality of results (QOR), including timing, routing, and power of the product. Some examples prevent isolation cells from being an ”anchor” for latch placement and provide more flexibility in latch repositioning. Some examples remove isolation cell influence from wire synthesis optimization to provide a more optimal wire synthesis solution on nets with isolation cells. Some examples are applicable to all gate level designs that use isolation cells. Some examples combine a tool command language (TCL) placement routine to move isolation cells and EDA placement routines together for optimal isolation cell placement. Some examples eliminate “scenic” isolation cell placement, provide wiring congestion improvement and timing figure of merit (FOM) improvement, and provide repeatable optimization for highly engineered constructs.

An example of the present disclosure is directed to a method, which includes placing a plurality of cells, including a plurality of latches and an isolation cell, at initial positions based on a first set of one or more design aspects thereby creating an integrated circuit layout, where the isolation cell is configured to isolate circuitry in response to a received control signal. The method includes performing a first optimization on the integrated circuit layout with the plurality of cells at the initial positions, including repositioning the plurality of latches and the isolation cell, concurrently, in the integrated circuit layout based on a second set of one or more design aspects.

In some examples of the method, the first set of one or more design aspects includes wire length. In some examples of the method, the second set of one or more design aspects includes timing constraints.

Some examples of the method further include performing a first position refinement for the isolation cell after the repositioning, including moving the isolation cell closer to a first cell of the plurality of cells that is a source for the isolation cell or closer to a second cell of the plurality of cells that is a sink for the isolation cell, where the first position refinement is based on a third set of one or more design aspects. In some examples, the third set of one or more design aspects comprises one or more of power at an input net of the isolation cell, power at an output net of the isolation cell, and output net fanout of the isolation cell.

Some examples of the method further include huddling the plurality of latches with a local clock buffer; determining, after the huddling, whether further position refinement of the isolation cell is to be performed; and performing, in response to determining that further position refinement of the isolation cell is to be performed, a second position refinement of the isolation cell, including moving the isolation cell again based on the third set of one or more design aspects.

In some examples of the method, performing the first position refinement further includes moving the isolation cell closer to the first cell of the plurality of cells in response to power at an input net of the isolation cell not being equal to power at an output net of the isolation cell and the power at the input net of the isolation cell being equal to circuit power for the isolation cell. In some examples of the method, performing the first position refinement further includes moving the isolation cell closer to the second cell of the plurality of cells in response to an output net fanout of the isolation cell being equal to one; and moving the isolation cell closer to the first cell of the plurality of cells in response to an output net fanout of the isolation cell being greater than one. In some examples of the method, performing the first position refinement further includes adding one or more additional isolation cells to the integrated circuit layout in response to an output net fanout of the isolation cell being greater than one; and positioning the isolation cell and the one or more additional isolation cells adjacent to respective cells acting as sinks.

Another example of the present disclosure is directed to a computer system, which includes a processor set, and one or more computer-readable storage media. The computer system includes program instructions stored on the one or more storage media to cause the processor set to perform operations including placing a plurality of cells, including a plurality of latches and an isolation cell, at initial positions based on a first set of one or more design aspects thereby creating an integrated circuit layout, where the isolation cell is configured to isolate circuitry in response to a received control signal. The operations further include performing a first optimization on the integrated circuit layout with the plurality of cells at the initial positions, including repositioning the plurality of latches and the isolation cell, concurrently, in the integrated circuit layout based on a second set of one or more design aspects.

In some examples of the computer system, the first set of one or more design aspects includes wire length. In some examples of the computer system, the second set of one or more design aspects includes timing constraints.

In some examples of the computer system, the operations further include performing a first position refinement for the isolation cell after the repositioning, including moving the isolation cell closer to a first cell of the plurality of cells that is a source for the isolation cell or closer to a second cell of the plurality of cells that is a sink for the isolation cell, where the first position refinement is based on a third set of one or more design aspects. In some examples of the computer system, the third set of one or more design aspects comprises one or more of power at an input net of the isolation cell, power at an output net of the isolation cell, and output net fanout of the isolation cell.

In some examples of the computer system, the operations further include huddling the plurality of latches with a local clock buffer; determining, after the huddling, whether further position refinement of the isolation cell is to be performed; and performing, in response to determining that further position refinement of the isolation cell is to be performed, a second position refinement of the isolation cell, including moving the isolation cell again based on the third set of one or more design aspects.

Another example of the present disclosure is directed to a computer program product, which includes one or more computer-readable storage media. The computer program product includes program instructions stored on the one or more storage media to perform operations including placing a plurality of cells, including a plurality of latches and an isolation cell, at initial positions based on a first set of one or more design aspects thereby creating an integrated circuit layout, where the isolation cell is configured to isolate circuitry in response to a received control signal. The operations further include performing a first optimization on the integrated circuit layout with the plurality of cells at the initial positions, including repositioning the plurality of latches and the isolation cell, concurrently, in the integrated circuit layout based on a second set of one or more design aspects.

In some examples of the computer program product, the first set of one or more design aspects includes wire length. In some examples of the computer program product, the second set of one or more design aspects includes timing constraints.

In some examples of the computer program product, the operations further include performing a first position refinement for the isolation cell after the repositioning, including moving the isolation cell closer to a first cell of the plurality of cells that is a source for the isolation cell or closer to a second cell of the plurality of cells that is a sink for the isolation cell, where the first position refinement is based on a third set of one or more design aspects. In some examples of the computer program product, the third set of one or more design aspects includes one or more of power at an input net of the isolation cell, power at an output net of the isolation cell, and output net fanout of the isolation cell.

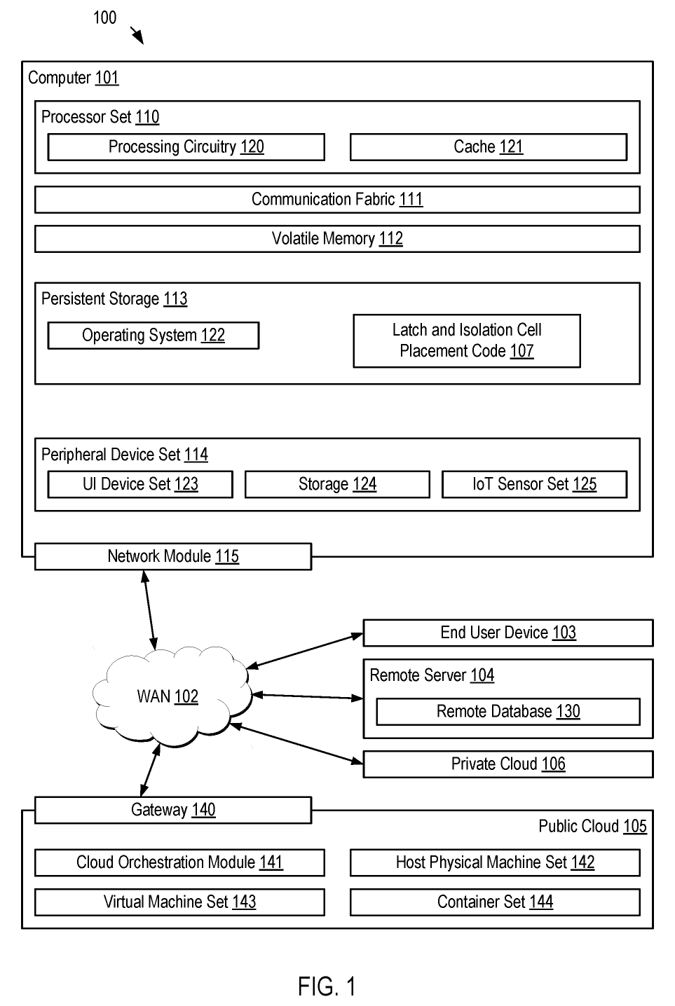

FIG. 1 sets forth an example computing environment according to aspects of the present disclosure. Computing environment 100 contains an example of an environment for the execution of at least some of the computer code involved in performing the various methods described herein, such as latch and isolation cell placement code 107. In addition to latch and isolation cell placement code 107, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and latch and isolation cell placement code 107, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document. These computer readable program instructions are stored in various types of computer readable storage media, such as cache 121 and the other storage media discussed below. The program instructions, and associated data, are accessed by processor set 110 to control and direct performance of the computer-implemented methods. In computing environment 100, at least some of the instructions for performing the computer-implemented methods may be stored in latch and isolation cell placement code 107 in persistent storage 113.

Communication fabric 111 is the signal conduction path that allows the various components of computer 101 to communicate with each other. Typically, this fabric is made of switches and electrically conductive paths, such as the switches and electrically conductive paths that make up buses, bridges, physical input / output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in latch and isolation cell placement code 107 typically includes at least some of the computer code involved in performing the computer-implemented methods described herein.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database), this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the computer-implemented methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Cloud computing services and/or microservices (not separately shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider’s systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

The latch and isolation cell placement code 107 may function as an EDA tool, also referred to as an electronic computer-aided design (ECAD) tool. Electronic design automation is a category of software tools for designing electronic systems such as integrated circuits and printed circuit boards. The tools may work together in a design flow that chip designers use to design and analyze entire semiconductor chips. In some implementations, the computing environment 100 is coupled to, integrated with, and/or part of fabrication equipment at a manufacturing fabrication plant, and may communicate with and/or control operations of the fabrication equipment to thereby fabricate semiconductor devices. The manufacturing fabrication plant may build a photo mask from an integrated circuit layout as a physical design, and then build the actual product using the photo mask. The product may be an integrated circuit on a wafer according to the integrated circuit layout. There may be numerous integrated circuits on a wafer, and each integrated circuit may be diced into an individual chip.

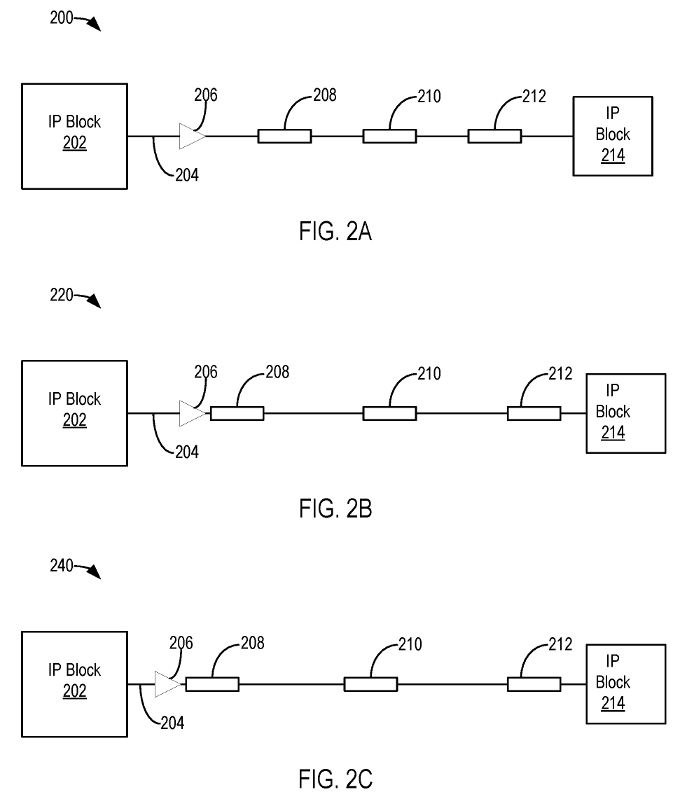

FIGS. 2A-2C set forth example latch and isolation cell placements in an integrated circuit layout according to aspects of the present disclosure. FIG. 2A shows an integrated circuit layout 200, which includes Intellectual Property (IP) blocks 202 and 214, isolation cell 206, and latches 208, 210, and 212. Isolation cell 206 and latches 208, 210, and 212 are coupled in series between IP blocks 202 and 214 along path 204. An input of isolation cell 206 is coupled to an output of IP block 202, and IP block 202 is a source of isolation cell 206. An output of isolation cell 206 is coupled to an input of latch 208, and latch 208 is a sink of isolation cell 206. An output of latch 208 is coupled to an input of latch 210. An output of latch 210 is coupled to an input of latch 212. An output of latch 212 is coupled to an input of IP block 214. Isolation cell 206 (which may also be referred to as a “fence”) is configured to be connected to a control signal (not shown) to control when the isolation cell is in an isolation state (i.e., blocking transmission from input to output). Thus, in the isolation state, isolation cell 206 will block transmission of signals from IP block 202 to latches 208, 210, and 212, and IP block 214. Integrated circuit layout 200 may represent an initial placement of cells, including the isolation cell 206 and the latches 208, 210, and 212, and may be based on a first set of one or more design aspects, such as wire length, so that the initial placement is performed in a manner to minimize wire length of the design.

FIG. 2B shows an integrated circuit layout 220, which represents the integrated circuit layout 200 (FIG. 2A) after repositioning of the latches 208, 210, and 212. For example, the latches 208, 210, and 212 may be repositioned based on a second set of one or more design aspects, such as timing constraints, so that the repositioning is performed in a manner to optimize timing of the layout. The positions of the latches 208, 210, and 212 in FIG. 2B have been spread out evenly from the initial positions shown in FIG. 2A. In this example, the position of the isolation cell 206 is locked in place and acts as an anchor, so the movement of the latches 208, 210, and 212 is constrained by the position of the isolation cell 206. For example, latch 208 may be prohibited from being moved any farther to the left since it is blocked by the isolation cell 206. Constraining the movement of the latches 208, 210, and 212 in this manner may result in, for example, a timing slack failure, which may involve manual intervention to address the issue.

FIG. 2C shows an integrated circuit layout 240, which represents the integrated circuit layout 200 (FIG. 2A) after concurrent repositioning of the isolation cell 206 and the latches 208, 210, and 212. For example, the isolation cell 206 and the latches 208, 210, and 212 may be repositioned based on the second set of one or more design aspects, such as timing constraints, so that the repositioning is performed in a manner to optimize timing of the layout. The positions of the latches 208, 210, and 212 in FIG. 2C have been spread out evenly from the initial positions shown in FIG. 2A (and more spread out than the positions shown in FIG. 2B). In this example, the position of the isolation cell 206 is not locked in place, but rather the isolation cell 206 is moved concurrently with the latches 208, 210, and 212 so that the movement of the latches 208, 210, and 212 is less constrained by the isolation cell 206. As shown in FIG. 2C, the isolation cell 206 and the latch 208 are both moved closer to the IP block 202 than shown in FIG. 2B.

In an example, the movement of the isolation cell 206 to reach the position shown in FIG. 2C involves two separate movements. In an example, the first movement of the isolation cell 206 is a concurrent movement with the latches 208, 210, and 212 based on the second set of one or more design aspects, and the second movement of the isolation cell 206 is a movement closer to a source of the isolation cell 206 (e.g., closer to IP block 202) or closer to a sink of the isolation cell (e.g., closer to latch 208) based on a third set of one or more design aspects (e.g., one or more of power at an input net of the isolation cell 206, power at an output net of the isolation cell 206, and output net fanout of the isolation cell 206). In some examples, the first movement of the isolation cell 206 may result in the isolation cell 206 being positioned midway between the source and the sink of the isolation cell 206, and the second movement of the isolation cell 206 may result in the isolation cell 206 being positioned immediately adjacent to either the source or the sink of the isolation cell 206. As shown in FIG. 2C, after the second movement, the isolation cell 206 is positioned immediately adjacent to the sink (i.e., latch 208), so that the isolation cell 206 is closer to the sink than the source (i.e., IP block 202). In an example, the second movement of the isolation cell 206 facilitates optimal wire synthesis for the layout. In some examples, additional movements of the isolation cell 206 and/or latches 208, 210, and 212 may be implemented, such as huddling of the latches 208, 210, and 212 with an LCB and further movement of the isolation cell 206 based on such huddling, as described in further detail below.

In some examples, the integrated circuit layouts 200, 220, and 240 may be generated using latch and isolation cell placement code 107 (FIG. 1) executing on computing environment 100. Although only a portion of an integrated circuit layout is shown in each of FIGS. 2A-2C, it will be understood that an integrated circuit layout may be made up of macro blocks having rows that are occupied by various cells (with each cell containing one or more transistors) that provides a useful layer of hierarchical abstraction for designing an integrated circuit that may contain billions of transistors. The latch and isolation cell placement code 107 may include one or more routines for placing latches 208, 210, and 212, one or more isolation cells such as isolation cell 206, and IP blocks 202 and 214 in a manner resulting in an integrated circuit layout in which the isolation cell 206 and latches 208, 210, and 212 have been positioned and repositioned as described herein. According to some examples, computing environment 100 may include additional code for placing functional cells and fill cells in order to complete an integrated circuit layout. Integrated circuit layouts 200, 220, and 240 may be used by a computing environment (e.g., computing environment 100) to build a semiconductor device (e.g., an integrated circuit).

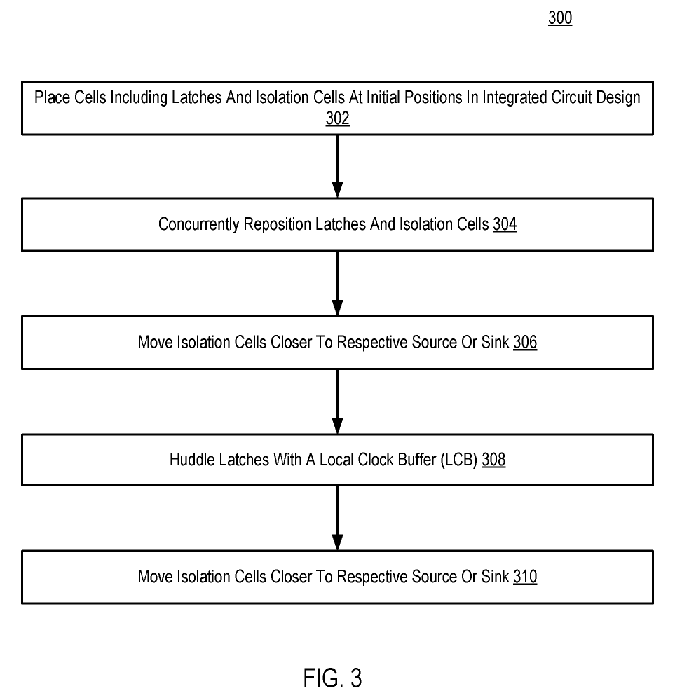

FIG. 3 a flowchart of an example method 300 for latch and isolation cell placement in an integrated circuit layout according to aspects of the present disclosure. In some examples, method 300 may be implemented by computing environment 100 using the latch and isolation cell placement code 107. Method 300 includes placing 302 cells, including latches and isolation cells, at initial positions in an integrated circuit design. The placing of cells may be based on a first set of one or more design aspects, such as wire length, so that the placement is performed in a manner to minimize wire length of the layout. In other examples, other design aspects may be used. After the initial placement, the design may not be optimized for timing, power, or routing. Method 300 includes concurrently repositioning 304 the latches and isolation cells. The repositioning may be based on a second set of one or more design aspects, such as timing constraints, so that the repositioning is performed in a manner to optimize timing of the layout.

The method 300 includes moving 306 the isolation cells closer to a respective source or sink of the isolation cell. Moving the isolation cells closer to a respective source or sink of the isolation cell may be based on a third set of one or more design aspects (e.g., one or more of power at an input net of the isolation cell, power at an output net of the isolation cell, and output net fanout of the isolation cell). The method 300 includes huddling 308 latches with an LCB. The method 300 includes moving 310 the isolation cells closer to a respective source or sink of the isolation cell. As with the moving 306 in method 300, the moving 310 may also be based on the third set of one or more design aspects (e.g., one or more of power at an input net of the isolation cell, power at an output net of the isolation cell, and output net fanout of the isolation cell).

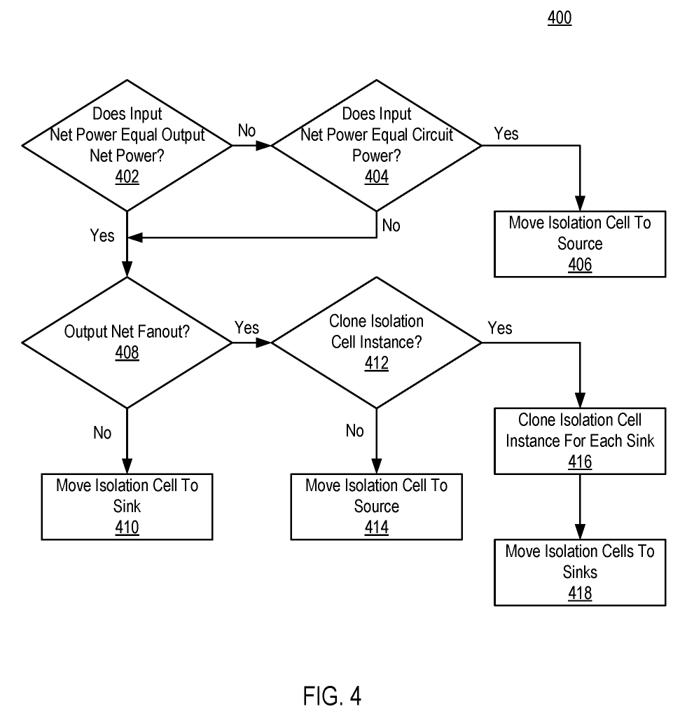

FIG. 4 is a flowchart of an example method 400 for isolation cell movement in an integrated circuit layout according to aspects of the present disclosure. In some examples, method 400 may be implemented by computing environment 100 using the latch and isolation cell placement code 107. In some examples, method 400 may be used for the moving 306 and the moving 310 in method 300 (FIG. 3). At 402, method 400 includes determining whether the input net power for an isolation cell (i.e., power or voltage level at an input net of the isolation cell) is equal to the output net power for the isolation cell (i.e., power or voltage level at an output net of the isolation cell). If it is determined at 402 that the input net power for the isolation cell is not equal to the output net power for the isolation cell, the method 400 moves to 404 to determine whether the input net power for the isolation cell is equal to the circuit power for the isolation cell. If it is determined at 404 that the input net power for the isolation cell is equal to the circuit power for the isolation cell, the isolation cell is moved at 406 to the source of the isolation cell (e.g., moved from a point midway between the source of the isolation cell and the sink of the isolation cell to a point closer to the source of the isolation cell, such as immediately adjacent to the source).

If it is determined at 402 that the input net power for the isolation cell is equal to the output net power for the isolation cell, or if it is determined at 404 that the input net power for the isolation cell is not equal to the circuit power for the isolation cell, the method 400 moves to 408 to determine whether the isolation cell has output net fanout (e.g., whether the isolation cell has more than one output driving more than one sink). If it is determined at 408 that the isolation cell does not have output net fanout (e.g., the isolation cell has a single output driving a single sink), the method 400 moves to 410 to move the isolation cell to the sink (e.g., moved from a point midway between the source of the isolation cell and the sink of the isolation cell to a point closer to the sink of the isolation cell, such as immediately adjacent to the sink). If it is determined at 408 that the isolation cell does have output net fanout (e.g., the isolation cell has a plurality of outputs driving a corresponding plurality of sinks), the method 400 moves to 412 to determine whether cloning of isolation cell instances is to be performed (e.g., whether isolation cell cloning is enabled). If it is determined at 412 that cloning of isolation cell instances is not to be performed, the method 400 moves to 414 to move the isolation cell to the source (e.g., moved from a point midway between the source of the isolation cell and the sinks of the isolation cell to a point closer to the source of the isolation cell, such as immediately adjacent to the source).

If it is determined that 412 that cloning of isolation cell instances is to be performed, the method 400 moves to 416 to clone the isolation cell instance to provide an isolation cell for each sink of the output net fanout. At 418, the method 400 includes moving the isolation cells to respective sinks of the output net fanout.

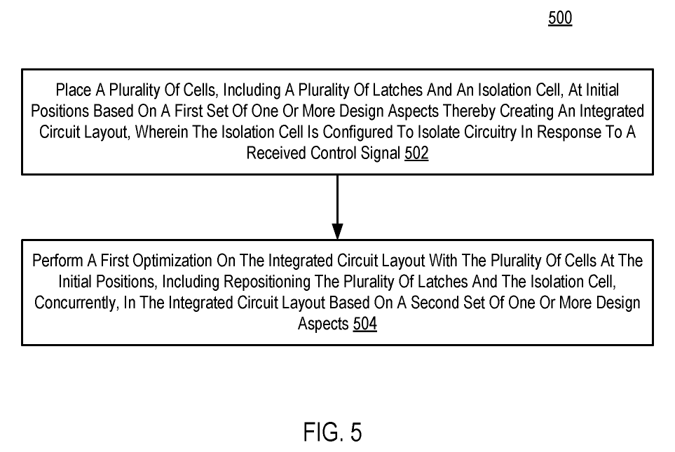

FIG. 5 is a flowchart of an example method 500 for unit and chip level isolation cell placement according to aspects of the present disclosure. In some examples, method 500 may be implemented by computing environment 100 using the latch and isolation cell placement code 107. The method 500 includes placing 502 a plurality of cells, including a plurality of latches and an isolation cell, at initial positions based on a first set of one or more design aspects thereby creating an integrated circuit layout, wherein the isolation cell is configured to isolate circuitry in response to a received control signal. The method 500 includes performing 504 a first optimization on the integrated circuit layout with the plurality of cells at the initial positions, including repositioning the plurality of latches and the isolation cell, concurrently, in the integrated circuit layout based on a second set of one or more design aspects.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment ("CPP embodiment" or “CPP”) is a term used in the present disclosure to describe any set of one, or more, storage media (also called "mediums") collectively included in a set of one, or more, storage devices that collectively include machine readable code corresponding to instructions and/or data for performing computer operations specified in a given CPP claim. A "storage device" is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
placing a plurality of cells, including a plurality of latches and an isolation cell, at initial positions based on a first set of one or more design aspects thereby creating an integrated circuit layout, wherein the isolation cell is configured to isolate circuitry in response to a received control signal; and
performing a first optimization on the integrated circuit layout with the plurality of cells at the initial positions, including repositioning the plurality of latches and the isolation cell, concurrently, in the integrated circuit layout based on a second set of one or more design aspects.

2. The method of claim 1, wherein the first set of one or more design aspects comprises wire length.

3. The method of claim 1, wherein the second set of one or more design aspects comprises timing constraints.

4. The method of claim 1, further comprising:
performing a first position refinement for the isolation cell after the repositioning, including moving the isolation cell closer to a first cell of the plurality of cells that is a source for the isolation cell or closer to a second cell of the plurality of cells that is a sink for the isolation cell, wherein the first position refinement is based on a third set of one or more design aspects.

5. The method of claim 4, wherein the third set of one or more design aspects comprises one or more of power at an input net of the isolation cell, power at an output net of the isolation cell, and output net fanout of the isolation cell.

6. The method of claim 4, further comprising:
huddling the plurality of latches with a local clock buffer;
determining, after the huddling, whether further position refinement of the isolation cell is to be performed; and
performing, in response to determining that further position refinement of the isolation cell is to be performed, a second position refinement of the isolation cell, including moving the isolation cell again based on the third set of one or more design aspects.

7. The method of claim 4, wherein performing the first position refinement further comprises:
moving the isolation cell closer to the first cell of the plurality of cells in response to power at an input net of the isolation cell not being equal to power at an output net of the isolation cell and the power at the input net of the isolation cell being equal to circuit power for the isolation cell.

8. The method of claim 4, wherein performing the first position refinement further comprises:
moving the isolation cell closer to the second cell of the plurality of cells in response to an output net fanout of the isolation cell being equal to one; and
moving the isolation cell closer to the first cell of the plurality of cells in response to an output net fanout of the isolation cell being greater than one.

9. The method of claim 4, wherein performing the first position refinement further comprises:
adding one or more additional isolation cells to the integrated circuit layout in response to an output net fanout of the isolation cell being greater than one; and
positioning the isolation cell and the one or more additional isolation cells adjacent to respective cells acting as sinks.

10. A computer system comprising:
a processor set;
one or more computer-readable storage media; and
program instructions stored on the one or more storage media to cause the processor set to perform operations comprising:
placing a plurality of cells, including a plurality of latches and an isolation cell, at initial positions based on a first set of one or more design aspects thereby creating an integrated circuit layout, wherein the isolation cell is configured to isolate circuitry in response to a received control signal; and
performing a first optimization on the integrated circuit layout with the plurality of cells at the initial positions, including repositioning the plurality of latches and the isolation cell, concurrently, in the integrated circuit layout based on a second set of one or more design aspects.

11. The computer system of claim 10, wherein the first set of one or more design aspects comprises wire length.

12. The computer system of claim 10, wherein the second set of one or more design aspects comprises timing constraints.

13. The computer system of claim 10, wherein the operations further comprise:
performing a first position refinement for the isolation cell after the repositioning, including moving the isolation cell closer to a first cell of the plurality of cells that is a source for the isolation cell or closer to a second cell of the plurality of cells that is a sink for the isolation cell, wherein the first position refinement is based on a third set of one or more design aspects.

14. The computer system of claim 13, wherein the third set of one or more design aspects comprises one or more of power at an input net of the isolation cell, power at an output net of the isolation cell, and output net fanout of the isolation cell.

15. The computer system of claim 13, wherein the operations further comprise:
huddling the plurality of latches with a local clock buffer;
determining, after the huddling, whether further position refinement of the isolation cell is to be performed; and
performing, in response to determining that further position refinement of the isolation cell is to be performed, a second position refinement of the isolation cell, including moving the isolation cell again based on the third set of one or more design aspects.

16. A computer program product comprising:
one or more computer-readable storage media; and
program instructions stored on the one or more storage media to perform operations comprising:
placing a plurality of cells, including a plurality of latches and an isolation cell, at initial positions based on a first set of one or more design aspects thereby creating an integrated circuit layout, wherein the isolation cell is configured to isolate circuitry in response to a received control signal; and
performing a first optimization on the integrated circuit layout with the plurality of cells at the initial positions, including repositioning the plurality of latches and the isolation cell, concurrently, in the integrated circuit layout based on a second set of one or more design aspects.

17. The computer program product of claim 16, wherein the first set of one or more design aspects comprises wire length.

18. The computer program product of claim 16, wherein the second set of one or more design aspects comprises timing constraints.

19. The computer program product of claim 16, wherein the operations further comprise:
performing a first position refinement for the isolation cell after the repositioning, including moving the isolation cell closer to a first cell of the plurality of cells that is a source for the isolation cell or closer to a second cell of the plurality of cells that is a sink for the isolation cell, wherein the first position refinement is based on a third set of one or more design aspects.

20. The computer program product of claim 19, wherein the third set of one or more design aspects comprises one or more of power at an input net of the isolation cell, power at an output net of the isolation cell, and output net fanout of the isolation cell.
